(19) United States
(12) Patent Application Publication
(10) Pub. No.: US 2015/0102862 A1
(43) Pub. Date: Apr. 16, 2015

(54) OSCILLATOR

(71) Applicant: NIHON DEMPA KOGYO CO., LTD., Tokyo (JP)

(72) Inventors: CHISATO ISHIMARU, SAITAMA (JP); SHIGEYOSHI MURASE, SAITAMA (JP)

(21) Appl. No.: 14/470,958

(22) Filed: Aug. 28, 2014

(30) Foreign Application Priority Data
Oct. 15, 2013 (JP) 2013-215062

(51) Int. Cl. H03B 19/00

(52) U.S. Cl. CPC H03B 19/00
USPC 331/60

(57) ABSTRACT

The oscillator is provided with an oscillator 10 which generates an oscillation signal, a first frequency division part 11 which generates a first frequency-divided signal by dividing the oscillation signal by a first frequency division ratio, a second frequency division part 12 which generates a second frequency-divided signal by dividing the oscillation signal by a second frequency division ratio, a first delay part 13 which generates a first delay signal, whose signal level changes at a timing different from the second frequency-divided signal, by delaying the first frequency-divided signal, a first output terminal 21 which outputs the first delay signal, and a second output signal 22 which outputs the second frequency-divided signal. Therefore, it is possible to prevent the levels of a plurality of signals from changing at the same time.

### CROSS-REFERENCE TO RELATED APPLICATIONS

This application claims the priority benefit of Japan application serial no. 2013-215062, filed on Oct. 15, 2013. The entirety of the above-mentioned patent application is hereby incorporated by reference herein and made a part of this specification.

### TECHNICAL FIELD

The present disclosure relates to an oscillator which outputs a plurality of oscillation signals of different frequencies.

### BACKGROUND OF THE INVENTION

Conventionally, oscillators which can output signals of two or more frequencies are known. In a conventional oscillator, a first frequency-divided signal is generated by dividing an original oscillation signal, a second frequency-divided signal is generated by dividing the first frequency-divided signal, and the first frequency-divided signal and the second frequency-divided signal of different frequencies are outputted (for example, see Japanese Unexamined Patent Application Publication No. 2006-303609).

In the conventional oscillator, the level of the first frequency-divided signal changes in synchronization with change timings of the level of the original oscillation signal, and the level of the second frequency-divided signal changes in synchronization with the change timings of the level of the first frequency-divided signal. FIG. 15 shows a relationship between the first frequency-divided signal and the second frequency-divided signal outputted from the conventional oscillator. The first frequency-divided signal is generated by dividing the original oscillation signal by four, and the second frequency-divided signal is generated by dividing the first frequency-divided signal by two.

The level of the first frequency-divided signal changes in synchronization with rising timings of the original signal, and the level of the second frequency-divided signal changes in synchronization with the rising timings of the first frequency-divided signal. Therefore, the timings when the level of the first frequency-divided signal and the level of the second frequency-divided signal change are almost at the same time, and are indicated by dotted lines, as seen.

When levels of a plurality of signals change at the same time, the amount of electric current supplied at the change timing of signal levels increases, which causes a fluctuation of a supply voltage, and this is not preferable. Further, because the signal at the change timing of the signal level includes more high frequency components than at other timings, the high frequency component radiated as an electric wave unfavorably increases, if the level of the first frequency-divided signal and the level of the second frequency-divided signal change at the same time.

### SUMMARY

The present disclosure is created in view of the aforementioned circumstances, and the present disclosure is to provide the oscillator capable of preventing the levels of the plurality of signals from changing at the same time while outputting the plurality of signals of different frequencies.

In the present disclosure, an oscillator that includes an oscillation part configured to generate an oscillation signal, a first frequency division part configured to generate a first frequency-divided signal by dividing the oscillation signal by a first frequency division ratio, a second frequency division part configured to generate a second frequency-divided signal by dividing the oscillation signal by a second frequency division ratio, a first delay part configured to generate a first delay signal, whose signal level changes at a timing different from the second frequency-divided signal, by delaying the first frequency-divided signal, a first output terminal which outputs the first delay signal, and a second output signal which outputs the second frequency-divided signal, is provided.

### BRIEF DESCRIPTION OF THE DRAWINGS

FIG. 1 shows a configuration of an oscillator according to the first exemplary embodiment.

FIG. 2 shows a relationship between a first delay signal and a second frequency-divided signal outputted from the oscillator according to the first exemplary embodiment.

FIG. 3 shows the configuration of the oscillator according to the second exemplary embodiment.

FIG. 4 is a table that shows frequencies of signals outputted from output terminals of the oscillator according to the second exemplary embodiment.

FIG. 5 shows the configuration of the oscillator according to the third exemplary embodiment.

FIG. 6 is a table that shows frequencies of signals outputted from the output terminals of the oscillator according to the third exemplary embodiment.

FIG. 7 is a timing diagram of signals outputted from the output terminals of the oscillator according to the third exemplary embodiment.

FIG. 8 shows the configuration of the oscillator according to the fourth exemplary embodiment.

FIG. 9 is a table that shows frequencies of signals outputted from the output terminals of the oscillator according to the fourth exemplary embodiment.

FIG. 10A is a timing diagram of the signal outputted from the output terminals of the oscillator according to the fourth exemplary embodiment.

FIG. 10B is a timing diagram of the signals outputted from the output terminals of the oscillator according to the fourth exemplary embodiment.

FIG. 11 shows the configuration of the oscillator according to the fifth exemplary embodiment.

FIG. 12 is a table that shows frequencies of signals outputted from the output terminals of the oscillator according to the fifth exemplary embodiment.

FIG. 13 shows the configuration of the oscillator according to the sixth exemplary embodiment.

FIG. 14 shows the configuration of the oscillator according to the seventh exemplary embodiment.

FIG. 15 shows a relationship between a first frequency-divided signal and a second frequency-divided signal outputted from a conventional oscillator.

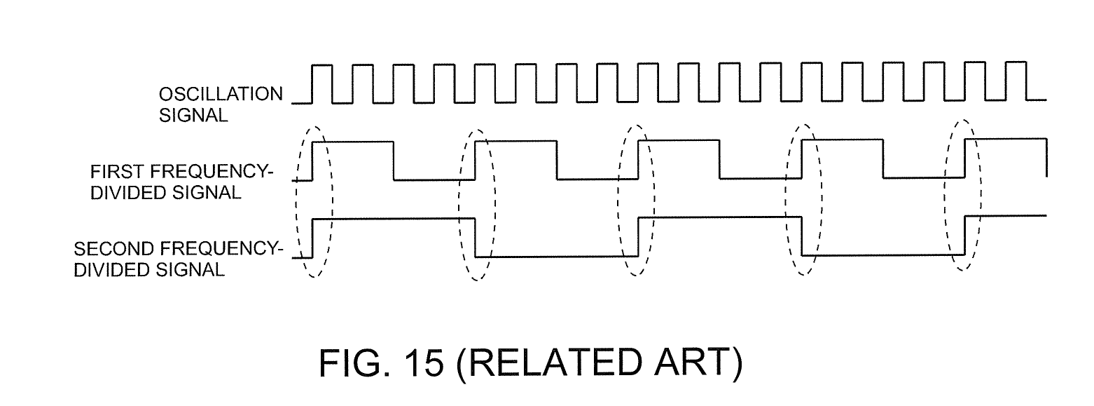

### DESCRIPTION OF EXEMPLARY EMBODIMENTS

### The First Exemplary Embodiment

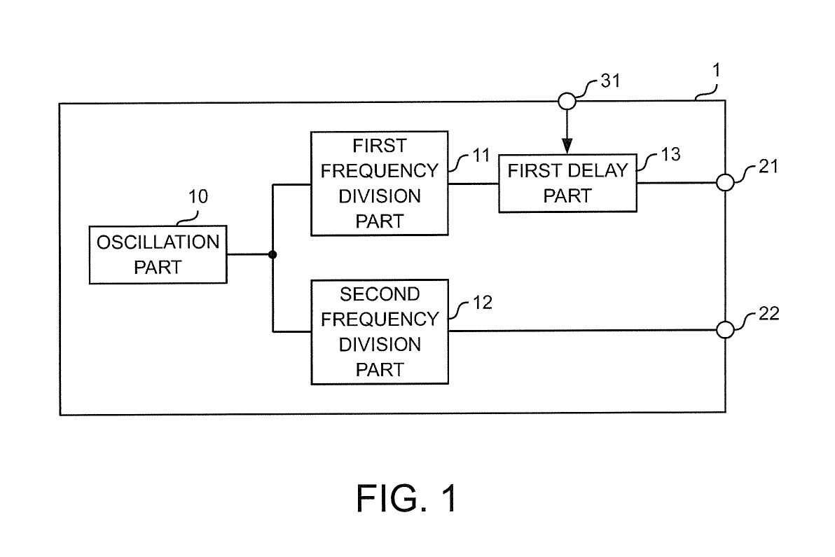

FIG. 1 shows a configuration of an oscillator 1 according to the first exemplary embodiment. The oscillator 1 is provided with an oscillation part 10, a first frequency division part 11, a second frequency division part 12, a first delay part 13, an output terminal 21, an output terminal 22, and a control terminal 31.

The oscillation part 10 includes, for example, a resonator such as a crystal resonator or a micro-electro-mechanical system (MEMS) resonator and an oscillation circuit which oscillates the resonator. The oscillation part 10 generates and outputs a sine-wave-like or a square-wave-like oscillation signal of the first frequency. The oscillation part 10 outputs, for example, an oscillation signal which oscillates at an overtone frequency of a resonance frequency of the crystal resonator or the MEMS resonator.

The first frequency division part 11 divides an oscillation signal outputted from the oscillation part 10 by a first frequency dividing ratio, and generates a first frequency-divided signal whose frequency is lower than the first frequency. When T represents a period of the oscillation signal and M represents the first frequency dividing ratio (M is an integer equal to or larger than 2), the first frequency division part 11 generates the first frequency-divided signal, which rises in synchronization with rising timings of the oscillation signal and whose period is T×M.

The second frequency division part 12 divides the oscillation signal outputted from the oscillation part 10 by a second frequency dividing ratio, and generates a second frequency-divided signal whose frequency is lower than the second frequency. When T represents the period of the oscillation signal and N represents the second frequency dividing ratio (N is an integer larger than M), the second frequency division part 12 generates the second frequency-divided signal, which rises in synchronization with rising timings of the oscillation signal and whose period is T×N. The second frequency-divided signal is outputted from the output terminal 22.

The first delay part 13 generates a first delay signal, whose signal level changes at a timing different from the change timing of the second frequency-divided signal, by delaying the first frequency-divided signal. The first delay part 13 delays the first frequency-divided signal, for example, in synchronization with the oscillation signal.

Specifically, the first delay part 13 includes, for example, a D-flip-flop, and the oscillation signal outputted from the oscillation part 10 is inputted to a clock input stage of the D-flip-flop. The first frequency-divided signal which is outputted from the first frequency division part 11 is inputted to a data input stage of the D-flip-flop. The first delay part 13 latches the first frequency-divided signal inputted to the data input stage at a falling timing of the oscillation signal inputted to the clock input stage, and outputs the latched signal. By this means, the first frequency-divided signal, whose signal level changes in synchronization with the rising timings of the oscillation signal, is delayed for a half period of the oscillation signal and is converted to a first delay signal, whose signal level changes in synchronization with the falling timings of the oscillation signal. The first delay signal is outputted from the output terminal 21.

The first delay part 13 may delay the first frequency-divided signal by using an element other than the flip-flop. For example, the first delay part 13 may delay the first frequency-divided signal using a delay line which operates asynchronously with the oscillation signal. The delay part 13 may use the flip-flop and the delay line in combination. When the first delay part 13 uses the flip-flop and the delay line, a time which is different from a multiple of the period of the oscillation signal is chosen for a delay time. The delay time is calculated to be, for example, T/2+kT+d (k is an integer equal to or larger than 0 and d is the delay time of the delay line).

The first delay part 13 changes the delay time of the first frequency-divided signal according to a control signal which is inputted from the control terminal 31. For example, when the first delay part 13 includes a plurality of the flip-flops, the first delay part 13 delays the first frequency-divided signal by using the flip-flops whose amounts of stages are indicated by the control signal. When the control signal indicates k, the first delay part 13 delays the first frequency-divided signal for T/2+kT (k is an integer equal to or larger than 0).

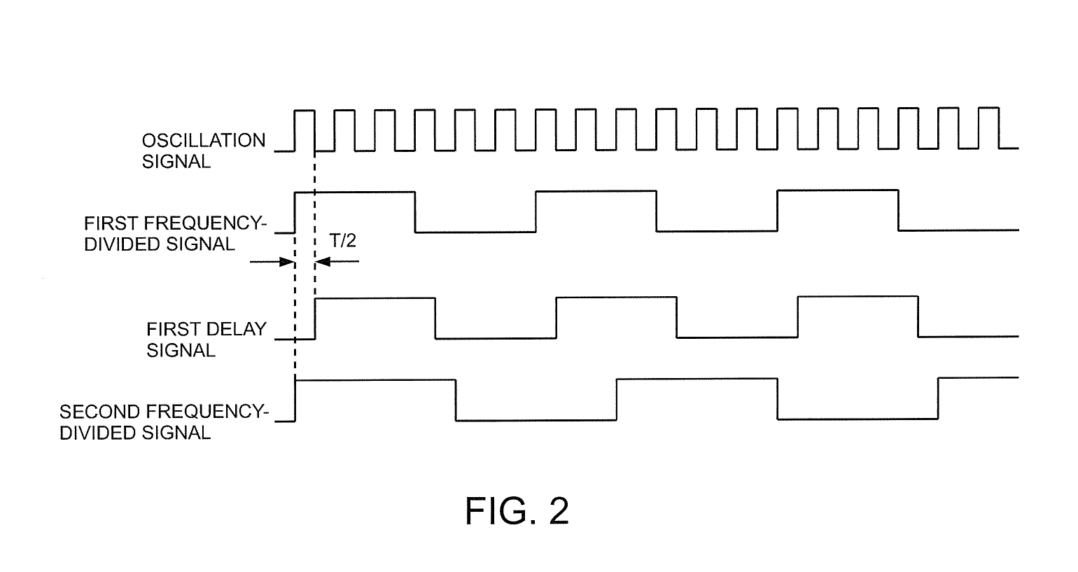

FIG. 2 shows a relationship between the first delay signal and the second frequency-divided signal outputted from the oscillator 1 according to the first exemplary embodiment. The oscillation signal is a square-wave-like signal of 144 MHz. The first frequency-divided signal is a signal generated by dividing the oscillation signal by six, and rises in synchronization with the rising timings of the oscillation signal at every six periods of the oscillation signal. The frequency of the first frequency-divided signal is 24 MHz.

The first delay signal is generated by latching the first frequency-divided signal at the falling edge of the oscillation signal, and is delayed for a half period of the oscillation signal from the first frequency-divided signal. Thus, the first delay signal rises in synchronization with the falling timings of the oscillation signal at every six periods of the oscillation signal.

The second frequency-divided signal is a signal generated by dividing the oscillation signal by eight, and rises in synchronization with the rising timings of the oscillation signal at every eight periods of the oscillation signal. The frequency of the second frequency-divided signal is 16 MHz.

The signal level of the first delay signal changes in synchronization with the falling timings of the oscillation signal, but the signal level of the second frequency-divided signal changes in synchronization with the rising timings of the oscillation signal. It is thus recognized that the signal levels of the first delay signal and the signal levels of the second frequency-divided signal do not change at the same time.

As described above, because the oscillator 1 according to the first exemplary embodiment is provided with the first delay part 13 which generates the first delay signal, whose signal level changes at a timing different from the second frequency-divided signal by delaying the first frequency-divided signal, the signal level of the first frequency-divided signal and the signal level of the second frequency-divided signal do not change at the same time. Thus, the oscillator 1 can output a plurality of signals of different frequencies whose signal levels do not change at the same time.

### The Second Exemplary Embodiment

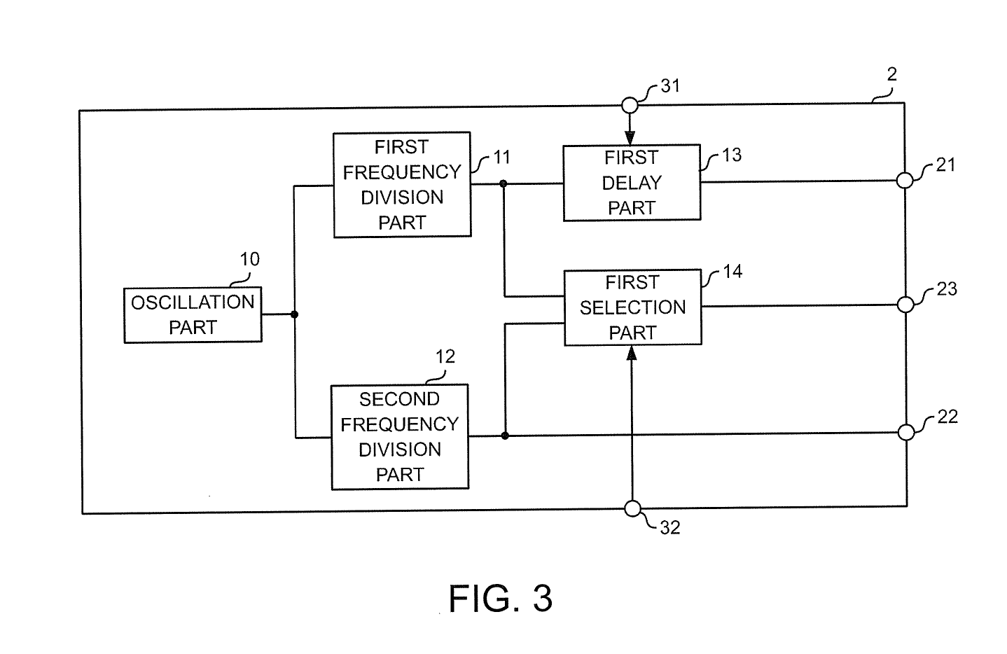

FIG. 3 shows a configuration of an oscillator 2 according to the second exemplary embodiment. The oscillator 2 is different from the oscillator 1 according to the first exemplary embodiment in that the oscillator 2 is further provided with a first selection part 14 which selects either the first frequency-divided signal or the second frequency-divided signal, and an output terminal 23 which outputs a signal selected by the first selection part 14. The first selection part 14 switches whether to output the first frequency-divided signal or to output the second frequency-divided signal, according to a selection signal inputted from a control terminal 32.

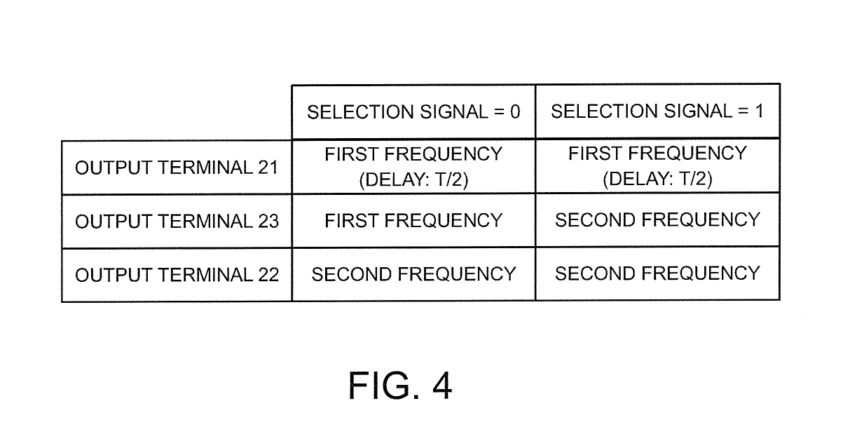

FIG. 4 is a table that shows frequencies of signals outputted from the output terminal 21, the output terminal 22, and the output terminal 23 of the oscillator 2. When a logical value of the selection signal inputted from the control terminal 32 is 0, the oscillator 2 outputs the first delay signal of the first frequency from the output terminal 21 (the delay time is T/2), the first frequency-divided signal of the first frequency from the output terminal 23 (the delay time is 0), and the second frequency-divided signal of the second frequency from the output terminal 22 (the delay time is 0). When the logical value of the selection signal inputted from the control terminal 32 is 1, the oscillator 2 outputs the first delay signal of the first frequency from the output terminal 21 (the delay time is T/2), and the second frequency-divided signal of the second frequency from the output terminal 22 and the output terminal 23 (the delay time is 0). The delay time herein is a time delayed from the rising timing of the first frequency-divided signal.

Thus, because the oscillator 2 can output either the first frequency-divided signal or the second frequency-divided signal according to the selection signal, an apparatus using the oscillator 2 can use a plurality of signals of the first frequency or a plurality of signals of the second frequency. Further, because at least one of the signals among the three signals which are outputted from the oscillator 2 changes at a timing different from a timing when the level of other signals change, it is possible to prevent the levels of the three signals from changing at the same time.

### The Third Exemplary Embodiment

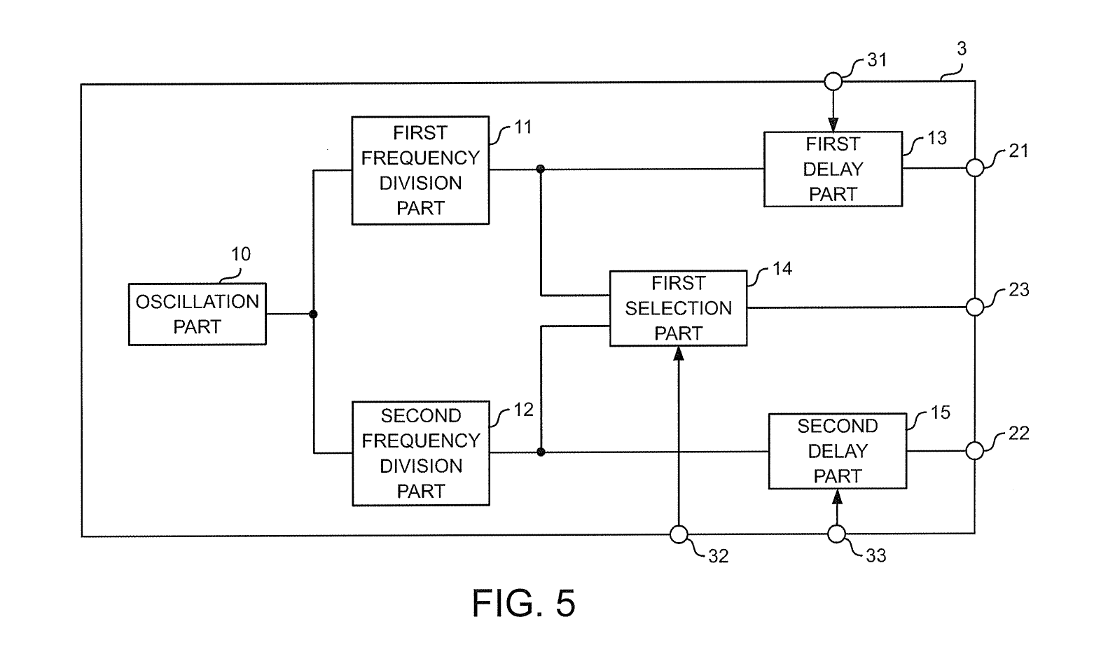

FIG. 5 shows a configuration of an oscillator 3 according to the third exemplary embodiment. The oscillator 3 is the same as the oscillator 2 shown in FIG. 3, except that the oscillator 3 has a second delay part 15 between the second frequency division part 12 and the output terminal 22. In the present exemplary embodiment, the first delay part 13 latches the first frequency-divided signal at the falling timing of the oscillation signal outputted from the oscillation part 10, and outputs the latched signal from the output terminal 21. The second delay part 15 generates the second delay signal, whose signal level changes at a timing different from the change timings of the first frequency-divided signal, the second frequency-divided signal, and the first delay signal, by delaying the second frequency-divided signal. The second delay part 15 determines the delay time according to, for example, the control signal inputted from the control terminal 33.

The second delay part 15 includes, for example, the D-flip-flop like the first delay part 13. The second delay part 15 latches the second frequency-divided signal at the rising timing of the oscillation signal, and outputs the latched signal from the output terminal 22. By this means, the signal levels of (i) the first delay signal outputted from the output terminal 21, (ii) the second delay signal outputted from the output terminal 22, and (iii) the signal that is selected by the first selection part 14 and is outputted from the output terminal 23 change at timings different from each other.

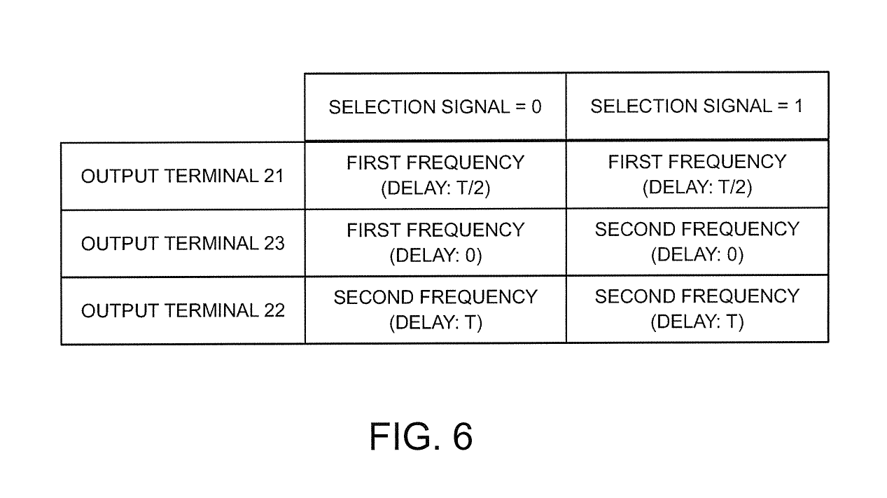

FIG. 6 is a table that shows frequencies of signals outputted from the output terminal 21, the output terminal 22, and the output terminal 23 of the oscillator 3. When the logic value of the selection signal inputted from the control terminal 32 is 0, the oscillator 3 outputs the first delay signal of the first frequency from the output terminal 21 (the delay time is T/2), the first frequency-divided signal of the first frequency from the output terminal 23 (the delay time is 0), and the second delay signal of the second frequency from the output terminal 22 (the delay time is T). When the logic value of the selection signal inputted from the control terminal 32 is 1, the oscillator 3 outputs the first delay signal of the first frequency from the output terminal 21 (the delay time is T/2), the second frequency-divided signal of the second frequency from the output terminal 23 (the delay time is 0), and the second delay signal of the second frequency from the output terminal 22 (the delay time is T). The delay time herein is a time delayed from the rising timing of the first frequency-divided signal.

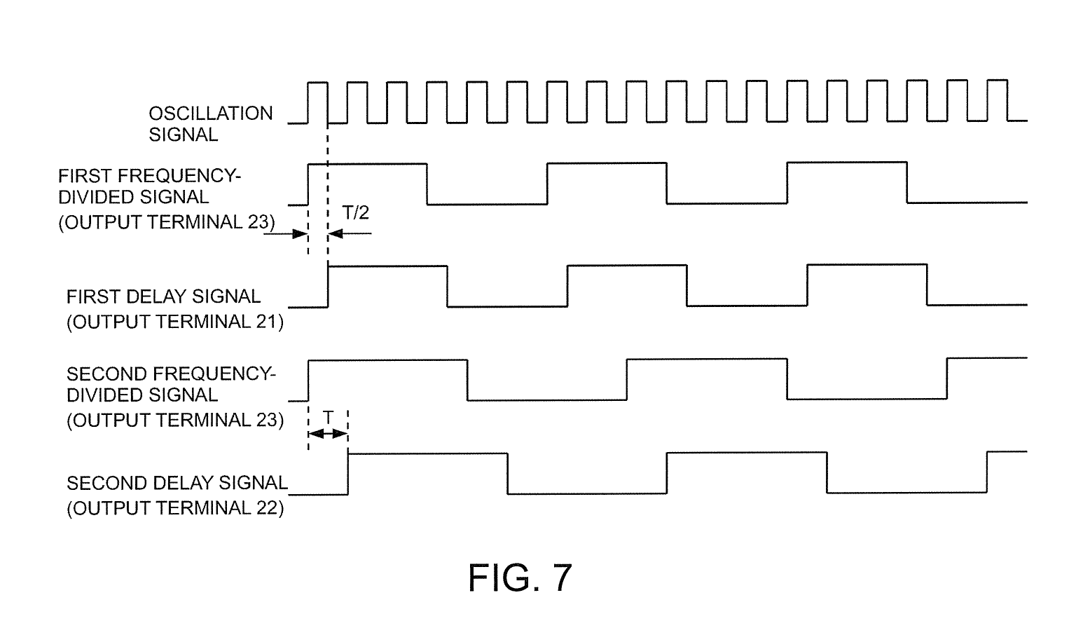

FIG. 7 is a timing diagram of signals outputted from the output terminal 21, the output terminal 22, and the output terminal 23 of the oscillator 3. The first frequency-divided signal is outputted from the output terminal 23 when the first selection part 14 selects the first frequency-divided signal, and the second frequency-divided signal is outputted from the output terminal 23 when the first selection part 14 selects the second frequency-divided signal. As is apparent from FIG. 7, whichever signal the first selection part 14 selects from the first frequency-divided signal and the second frequency-divided signal, the three signals outputted from the output terminal 21, the output terminal 22, and the output terminal 23 do not change at the same timing.

As described above, because the oscillator 3 is further provided with the second delay part 15 which delays the second frequency-divided signal, the oscillator 3 outputs the signal of the first frequency, the signal of the second frequency, and the signal of either the first frequency or the second frequency, and the signal level of each of the signals does not change at the same time. Thus, it is possible to prevent the levels of the three signals from changing at the same time.

### The Fourth Exemplary Embodiment

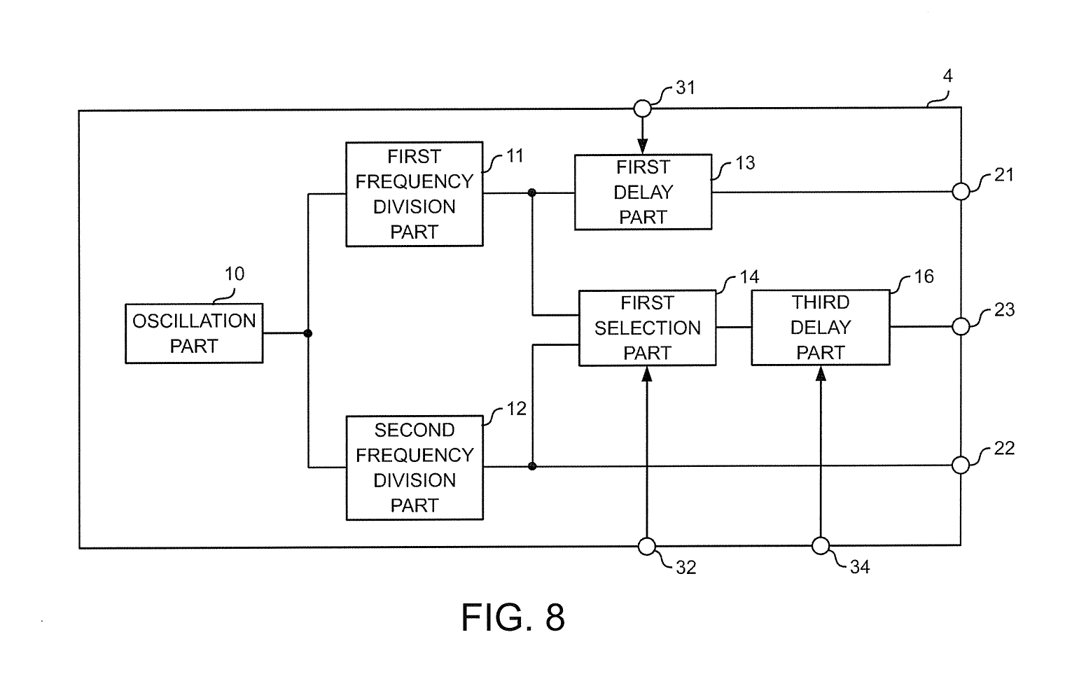

FIG. 8 shows a configuration of an oscillator 4 according to the fourth exemplary embodiment. The oscillator 4 is the same as the oscillator 2 shown in FIG. 3, except that the oscillator 4 has a third delay part 16 between the first selection part 14 and the output terminal 23. In the present exemplary embodiment, the first delay part 13 latches the first frequency-divided signal at the falling timing of the oscillation signal outputted from the oscillation part 10, and outputs the latched signal from the output terminal 21. The third delay part 16 generates a third delay signal, whose signal level changes at a timing different from the timing of the first frequency-divided signal and the second frequency-divided signal, by delaying the signal selected by the first selection part 14. The third delay part 16 switches the delay time according to which of the first frequency-divided signal and the second frequency-divided signal the first selection part 14 selected.

The third delay part 16 includes, for example, the D-flip-flop like the first delay part 13. The third delay part 16 switches whether to latch the signal selected by the first selection part 14 at the rising timing of the oscillation signal or to latch the signal at the falling timing according to which of the first frequency-divided signal and the second frequency-divided signal the first selection part 14 selected. The third delay part 16 switches whether to latch at the rising timing or to latch at the falling timing according to, for example, the control signal inputted from the control terminal 34.

The third delay part 16 may switch whether to latch at the rising timing or to latch at the falling timing according to the selection signal inputted from the control terminal 32. Further, the third delay part 16 may determine the delay time according to the control signal inputted from the control terminal 34 or the selection signal inputted from the control terminal 32.

When the first selection part 14 selects the first frequency-divided signal, the third delay part 16 latches the first frequency-divided signal selected by the first selection part 14 at the falling timing of the oscillation signal outputted from the oscillation part 10, and outputs the latched signal to the output terminal 23. The delay time of the third delay part 16 is different from the delay time of the first delay part 13. For example, when the delay time of the first delay part 13 is T/2, the delay time of the third delay part 16 is T/2+T.

By this means, the first delay signal outputted from the output terminal 21 and the third delay signal outputted from the output terminal 23 have different phases with the same frequency, and the signal levels do not change at the same time. Thus, the first delay signal outputted from the output terminal 21, the second frequency-divided signal outputted from the output terminal 22, and the third delay signal outputted from the output terminal 23 change at timings different from each other.

When the first selection part 14 selects the second frequency-divided signal, the third delay part 16 latches the second frequency-divided signal selected by the first selection part 14 at the rising timing of the oscillation signal outputted from the oscillation part 10, and outputs the latched signal to the output terminal 23. The delay time of the third delay part 16 is different from the delay time of the first delay part 13 and is also different from the period of the second frequency-divided signal.

Because the third delay part 16 latches the second frequency-divided signal at a timing different from the first delay part 13 when the first selection part 14 selects the second frequency-divided signal, the change timing of the first delay signal and the change timing of the third delay signal are not the same. Further, because the third delay signal is a signal generated by delaying the second frequency-divided signal, the change timing of the third delay signal and the change timing of the second frequency-divided signal are not the same, either. As a result, the signals outputted from the output terminal 21, the output terminal 22, and the output terminal 23 change at timings different from each other.

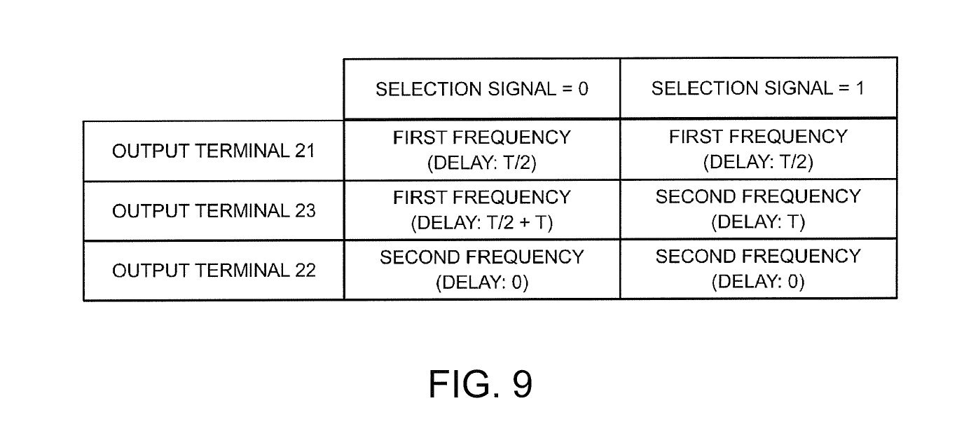

FIG. 9 is a table that shows frequencies of signals outputted from the output terminal 21, the output terminal 22, and the output terminal 23 of the oscillator 4. When the logic value of the selection signal inputted from the control terminal 32 is 0, the oscillator 4 outputs the first delay signal of the first frequency from the output terminal 21 (the delay time is T/2), the third delay signal of the first frequency from the output terminal 23 (the delay time is T/2+T), and the second frequency-divided signal of the second frequency from the output terminal 22 (the delay time is 0). When the logic value of the selection signal inputted from the control terminal 32 is 1, the oscillator 4 outputs the first delay signal of the first frequency from the output terminal 21 (the delay time is T/2), the third delay signal of the second frequency from the output terminal 23 (the delay time is T), and the second frequency-divided signal of the second frequency from the output terminal 22 (the delay time is 0). The delay time herein is a time delayed from the rising time of the first frequency-divided signal.

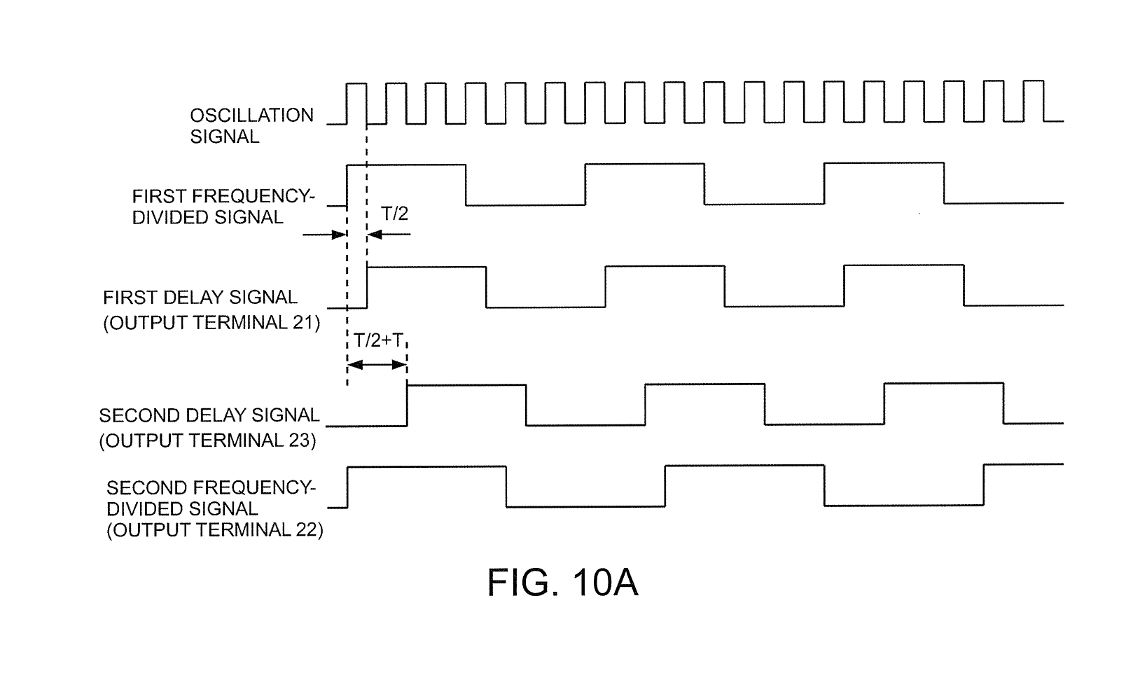

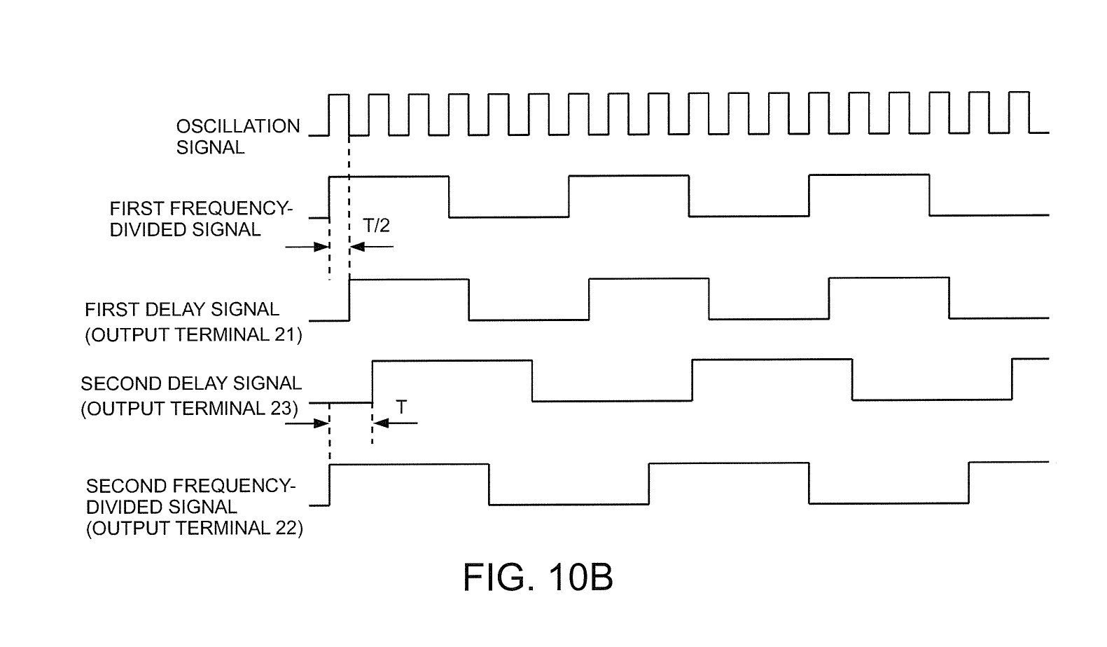

FIG. 10A and FIG. 10B are timing diagrams of the signals outputted from the output terminal 21, the output terminal 22, and the output terminal 23 of the oscillator 4. FIG. 10A is a timing diagram of the case when the logic value of the selection signal is 0, and FIG. 10B is a timing diagram of the case when the logic value of the selection diagram is 1. As is apparent from FIG. 10A and FIG. 10B, whichever signal the selection part 14 selects from the first frequency-divided signal and the second frequency-divided signal, the three signals outputted from the output terminal 21, the output terminal 22, and the output terminal 23 do not change at the same timing.

As described above, by changing the delay time of the third delay part 16 according to which of the first frequency-divided signal and the second frequency-divided signal the first selection part 14 selects, the oscillator 4 outputs the signal of the first frequency, the signal of the second frequency, and the signal of either the first frequency or the second frequency, and it is possible to prevent the levels of the three signals from changing at the same time.

### The Fifth Exemplary Embodiment

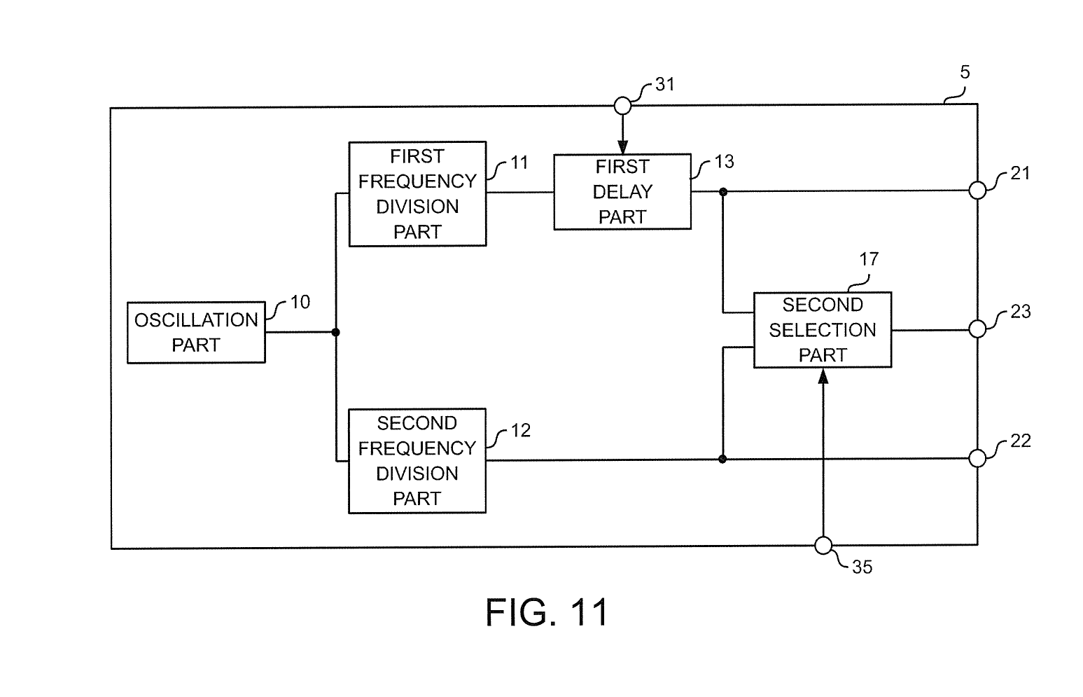

FIG. 11 shows a configuration of an oscillator 5 according to the fifth exemplary embodiment. The oscillator 5 is the same as the oscillator 1 according to the first exemplary embodiment, except that the oscillator 5 has a second selection part 17.

The second selection part 17 selects either the first delay signal that the first delay part 13 generates by delaying the first frequency-divided signal or the second frequency-divided signal that the second frequency division part 12 generates. The signal selected by the second selection part 17 is outputted from the output terminal 23.

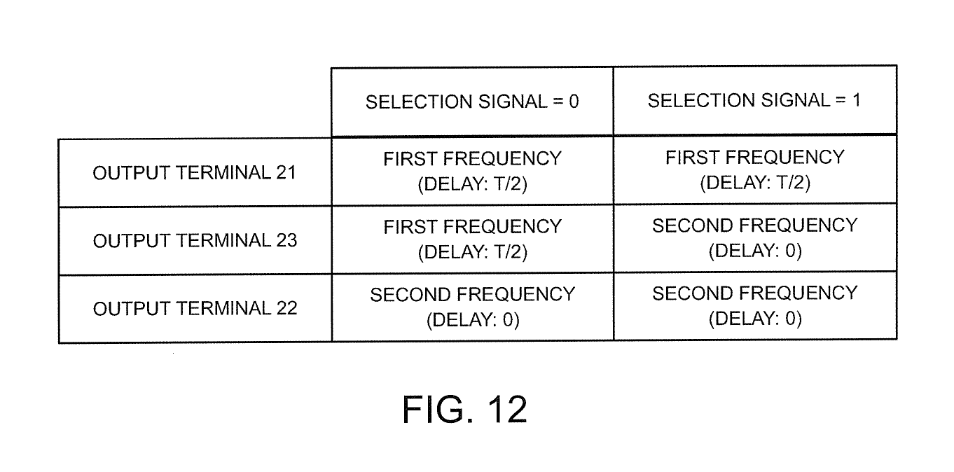

FIG. 12 is a table that shows frequencies of signals outputted from the output terminal 21, the output terminal 22, and the output terminal 23 of the oscillator 5. When the logic value of the selection signal inputted from the control terminal 35 is 0, the oscillator 5 outputs the first delay signal of the first frequency from the output terminal 21 and the output terminal 23 (the delay time is T/2), and the second frequency-divided signal of the second frequency from the output terminal 22 (the delay time is 0). When the logic value of the selection signal inputted from the control terminal 35 is 1, the oscillator 5 outputs the first delay signal of the first frequency from the output terminal 21 (the delay time is T/2), and the second frequency-divided signal of the second frequency from the output terminal 22 and the output terminal 23 (the delay time is 0).

Thus, the oscillator 5 outputs the signal of the first frequency, the signal of the second frequency, and the signal of the frequency selected from the first frequency and the second frequency. Further, the oscillator 5 does not let the signal of the first frequency and the signal of the second frequency change at the same time. Therefore, according to the oscillator 5, the levels of the three signals can be prevented from changing at the same time while the oscillator provides a plurality of signals of the same frequency.

### The Sixth Exemplary Embodiment

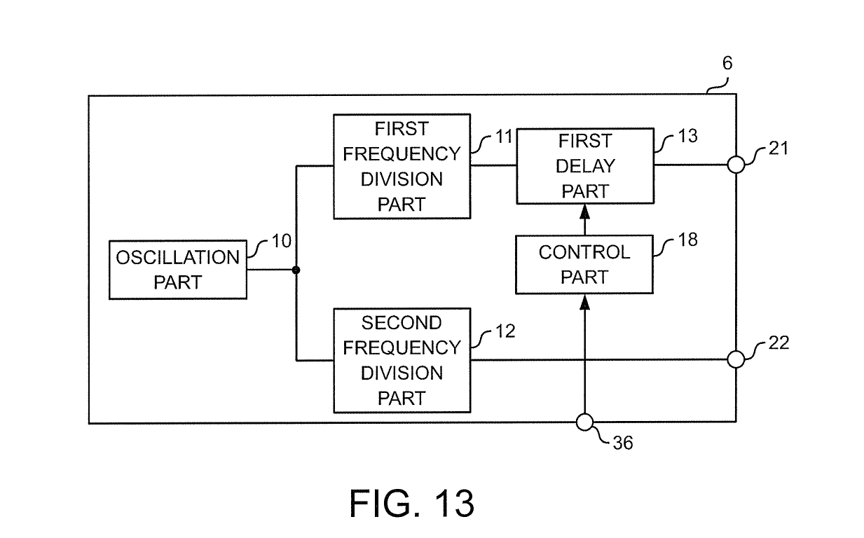

FIG. 13 shows a configuration of an oscillator 6 according to the sixth exemplary embodiment. The oscillator 6 is the same as the oscillator 1 according to the first exemplary embodiment, except that the oscillator 6 further has a control part 18 and a control terminal 36.

The control part 18 is, for example, a CPU and controls the delay time of the first delay part 13. The control part 18 controls the delay time of the first delay part 13 and the timing when the first delay part 13 latches the first frequency-divided signal according to data inputted from the control terminal 36. Accordingly, by providing the oscillator 6 with the control part 18, a timing relationship between the signal of the first frequency outputted from the output terminal 21 and the signal of the second frequency outputted from the output terminal 22 can be flexibly controlled according to states of a system using the oscillator 6.

Further, the oscillator 2, the oscillator 3, the oscillator 4, and the oscillator 5 according to the second, the third, the fourth and the fifth exemplary embodiments may be provided with the control part 18. In this case, the control part 18 controls the signal that the first selection part 14 and the second selection part 17 selects, the delay time of the second delay part 15 and the third delay part 16, and the timing of latching the signals inputted to the second delay part 15 and the third delay part 16 according to data inputted from the outside.

Thus, because the oscillator according to the present disclosure is provided with the control part 18, the oscillator can flexibly control the frequencies of the plurality of signals which are outputted and change timings of the levels of the plurality of signals while outputting the plurality of signals having different frequencies.

### The Seventh Exemplary Embodiment

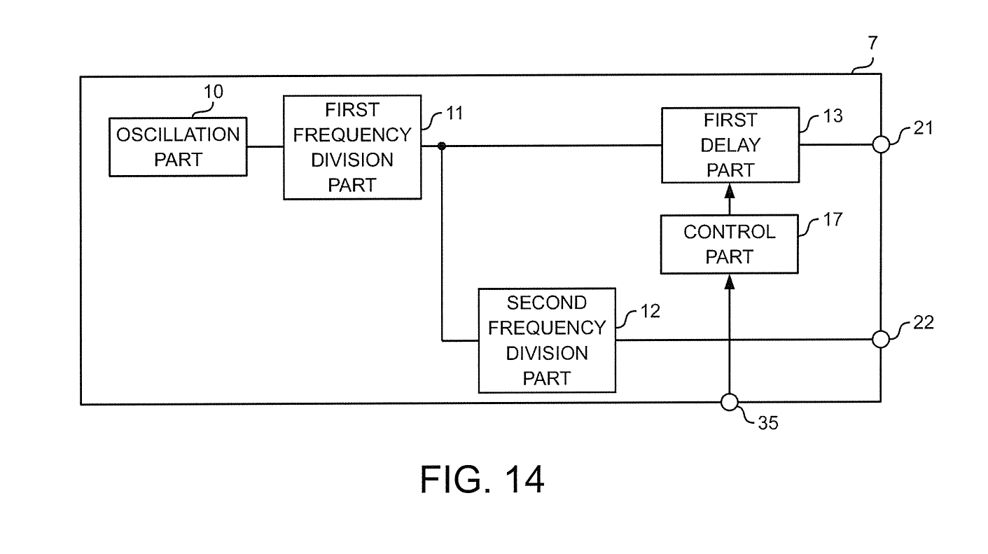

FIG. 14 shows a configuration of an oscillator 7 according to the seventh exemplary embodiment. The oscillator 7 is the same as the oscillator 1 shown in FIG. 1, except that the second frequency division part 12 generates the second frequency-divided signal by dividing the first frequency-divided signal outputted from the first frequency division part 11. In all of the above described exemplary embodiments, the frequency division part 12 may generate the second frequency-divided signal by dividing the first frequency-divided signal like this.

The present disclosure is described with the exemplary embodiments but the technical scope of the present disclosure is not limited to the scope described in the above embodiment. It is apparent for those skilled in the art that it is possible to make various changes and modifications to the embodiment. It is apparent from the description of the scope of the claims that the forms added with such changes and modifications are included in the technical scope of the present disclosure.

For example, by combining the flip-flop and the delay line like the first delay part 13, various delay times may be set in the second delay part 15 and the third delay part 16. Further, the oscillator may be provided with another frequency division part which outputs a third frequency-divided signal of a frequency different from the frequencies of the first frequency-divided signal and the second frequency-divided signal.

What is claimed is:

1. An oscillator, comprising:
an oscillation part configured to generate an oscillation signal;
a first frequency division part configured to generate a first frequency-divided signal by dividing the oscillation signal by a first frequency division ratio;
a second frequency division part configured to generate a second frequency-divided signal by dividing the oscillation signal by a second frequency division ratio;
a first delay part configured to generate a first delay signal, whose signal level changes at a timing different from the second frequency-divided signal, by delaying the first frequency-divided signal;
a first output terminal configured to output the first delay signal; and
a second output signal configured to output the second frequency-divided signal.

2. An oscillator according to claim 1, further comprising:
a first selection part configured to select either the first frequency-divided signal or the second frequency-divided signal; and
a third output terminal configured to output a signal selected by the first selection part.

3. An oscillator according to claim 2, further comprising:
a second delay part configured to generate a second delay signal, whose signal level changes at a timing different from the first frequency-divided signal, the second frequency-divided signal, and the first delay signal, by delaying the second frequency-divided signal, wherein
the second output terminal outputs the second delay signal as the second frequency-divided signal.

4. An oscillator according to claim 1, further comprising:
a first selection part configured to select either the first frequency-divided signal or the second frequency-divided signal;
a third delay part configured to generate a third delay signal, whose signal level changes at a timing different from the first frequency-divided signal and the second frequency-divided signal, by delaying a signal selected by the first selection part; and
a third output terminal configured to output the third delay signal generated by the third delay part.

5. An oscillator according to claim 4, wherein
the third delay part switches a delay time according to which of the first frequency-divided signal and the second frequency-divided signal the first selection part selected.

6. An oscillator according to claim 1, further comprising:
a second selection part configured to select either the first delay signal or the second frequency-divided signal; and
a third output terminal configured to output a signal selected by the second selection part.

7. An oscillator according to claim 1, wherein
the first delay part delays the first frequency-divided signal in synchronization with the oscillation signal.

8. An oscillator according to claim 1, further comprising:
a control part configured to control a delay time of the first delay part.
